(19) United States
(12) Patent Application Publication
(10) Pub. No.: US 2026/0298978 A1
(43) Pub. Date: Oct. 1, 2026

(54) PROBE APPARATUS

(71) Applicant: Kabushiki Kaisha Nihon Micronics, Tokyo (JP)

(72) Inventor: Tomoaki KUGA, Aomori (JP)

(21) Appl. No.: 18/996,441

(22) PCT Filed: Jun. 16, 2023
(86) PCT No.: PCT/JP2023/022461

§ 371 Date: Jan. 17, 2025

(30) Foreign Application Priority Data
Jul. 25, 2022 (JP) 2022-118020

(51) Int. Cl. G01R 1/067; G01R 31/28

(52) U.S. Cl. CPC G01R 1/06722; G01R 31/2886

(57) ABSTRACT

A probe apparatus includes: a housing that has a first surface and a second surface; a conductive probe that has a first contact portion exposed on the first surface and a second contact portion exposed on the second surface; and an elastic portion arranged inside the housing. A posture of the probe changes inside the housing. A position of a contact region in the second contact portion in contact with an electrode pad changes in response to a displacement of the first contact portion. The elastic portion has a first elastic member, and a second elastic member integrated with the first elastic member to reinforce an elastic force of the first elastic member. The elastic portion is elastically deformed in response to a change in the posture of the probe inside the housing, and biases the probe in a direction that cancels the displacement of the first contact portion.

### TECHNICAL FIELD

The present invention relates to a probe apparatus used for inspecting the electrical characteristics of a device.

### BACKGROUND

In inspecting the electrical characteristics of a device in which a semiconductor integrated circuit or the like is mounted on a package, a probe apparatus for electrically connecting a device and an inspection device has been used. The probe apparatus electrically connects an electrode terminal of the device and an electrode pad arranged on a substrate such as a printed circuit board (PCB). The electrode pad is electrically connected to the inspection device via a wiring pattern or the like formed on the substrate. For example, there is a probe apparatus including a conductive probe that simultaneously comes into contact with an electrode terminal and an electrode pad, and an elastic portion that controls a contact load applied to the probe when the probe comes into contact with the electrode terminal and the electrode pad by using elastic force (see Patent Literature 1).

### CITATION LIST

### Patent Literature

Patent Literature 1: JP 2019-35660 A

### SUMMARY OF THE INVENTION

### Technical Problem

In the probe apparatus that causes a contact load applied to the probe by an elastic force of the elastic portion, the elastic force of the elastic portion needs to be stable in order to stabilize the contact load. Further, in order to prevent a decrease in the elastic force of the elastic portion due to repeated measurement, it is desired to improve the durability of the elastic force of the elastic portion.

An object of the present invention is to provide a probe apparatus which improves the stability and durability of an elastic force of an elastic portion causing a contact load applied to a probe.

### Technical Solution

A probe apparatus according to an aspect of the present invention includes: a housing that has a first surface and a second surface; a conductive probe that has a first contact portion exposed on the first surface and a second contact portion exposed on the second surface; and an elastic portion that is arranged inside the housing. A posture of the probe changes inside the housing such that a position of a contact region in the second contact portion in contact with an electrode pad changes in response to a displacement of the first contact portion. The elastic portion has a first elastic member, and a second elastic member integrated with the first elastic member to reinforce an elastic force of the first elastic member. The elastic portion is elastically deformed in response to a change in the posture of the probe inside the housing, and biases the probe in a direction that cancels the displacement of the first contact portion.

### Effect of the Invention

The present invention makes it possible to provide a probe apparatus which improves the stability and durability of an elastic force of an elastic portion causing a contact load applied to a probe.

### BRIEF DESCRIPTION OF DRAWINGS

FIG. 1 is a schematic diagram illustrating a configuration of a probe apparatus according to a first embodiment.

FIG. 2 is a schematic cross-sectional view illustrating an elastic portion of the probe apparatus according to the first embodiment.

FIG. 3 is a schematic diagram illustrating a change in posture of a probe of the probe apparatus according to the first embodiment.

FIG. 4 is a schematic perspective view illustrating a structure of a second elastic member of a probe apparatus according to a modified example of the first embodiment.

FIG. 5 is a schematic cross-sectional view illustrating an elastic portion of the probe apparatus according to the modified example of the first embodiment.

FIG. 6 is a schematic diagram illustrating a configuration of a probe apparatus according to a second embodiment.

FIG. 7 is a schematic diagram illustrating an elastic portion of the probe apparatus according to the second embodiment.

FIG. 8 is a schematic diagram illustrating an example of an arrangement relationship between the probe and the elastic portion of the probe apparatus according to the second embodiment.

FIG. 9 is a schematic diagram illustrating an example of a configuration of a second elastic member of the probe apparatus according to the second embodiment.

FIG. 10 is a schematic perspective view illustrating an elastic portion of a probe apparatus according to a modified example of the second embodiment.

FIG. 11 is a schematic diagram illustrating a configuration of a probe apparatus according to a third embodiment.

FIG. 12 is a schematic diagram illustrating a configuration of a probe apparatus according to a modified example of the third embodiment.

FIG. 13 is a schematic diagram illustrating another configuration of the probe apparatus according to the modified example of the third embodiment.

### DETAILED DESCRIPTION OF THE INVENTION

Embodiments of the present invention will be described below with reference to the drawings. The same or similar elements illustrated in the drawings are denoted by the same or similar reference numerals. However, the drawings are illustrated schematically, and it should be noted that the proportions of the thicknesses or lengths of the respective parts and so forth are not drawn to scale. It should also be understood that the relationships or proportions of the dimensions between the respective drawings are different from each other in some elements. The embodiments described below exemplify a device and a method for embodying the technical idea of the present invention. In the embodiments of the present invention, the material, shape, structure, arrangement, manufacturing method and the like of the components are not limited to the following description.

### First Embodiment

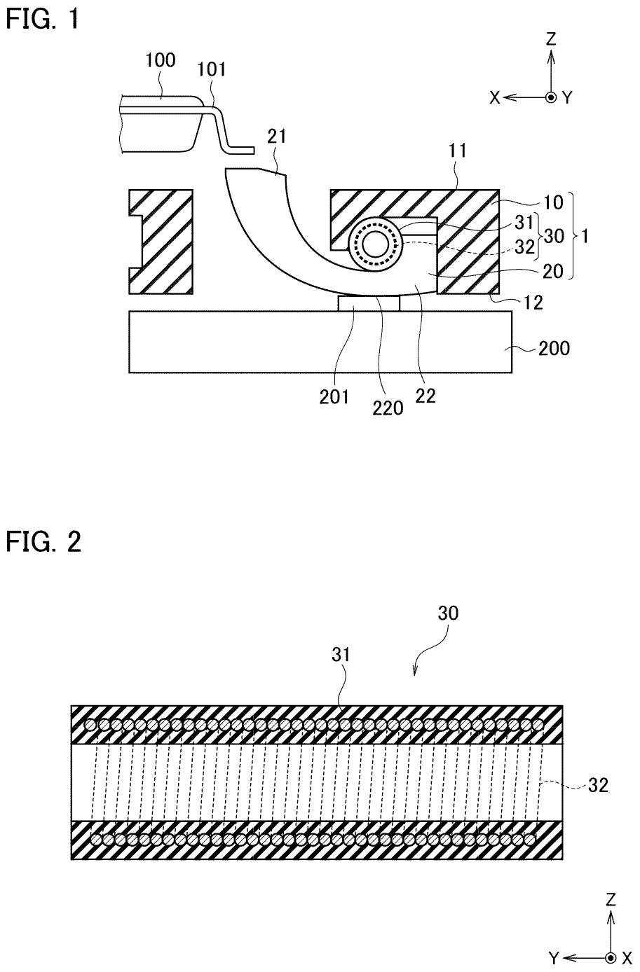

A probe apparatus 1 according to a first embodiment illustrated in FIG. 1 is used for inspecting the electrical characteristics of a device 100 to be inspected. The device 100 is an inspection object in which a semiconductor integrated circuit or the like is mounted on a package. The probe apparatus 1 electrically connects an electrode terminal 101 of the device 100 and an electrode pad 201 of a substrate 200. FIG. 1 exemplifies a case where the electrode terminal 101 is a lead electrode of the package. The electrode pad 201 is electrically connected to an inspection device via a wiring pattern (not illustrated) formed on the substrate 200.

The probe apparatus 1 includes a housing 10 having a first surface 11 and a second surface 12 facing the first surface 11, a conductive probe 20 having a first contact portion 21 and a second contact portion 22 and supported by the housing 10, and an elastic portion 30 arranged inside the housing 10. The probe 20 functions as a contactor for electrically connecting the electrode terminal 101 and the electrode pad 201. As a material of the probe 20, for example, a metal material such as a beryllium copper (Be—Cu) material or a palladium (Pd) alloy material is used. For example, the housing 10 is made of an insulating ceramic material.

The elastic portion 30 is arranged in the housing 10 and the probe 20, and arranged inside the housing 10. The elastic portion 30 has a first elastic member 31, and a second elastic member 32 integrated with the first elastic member 31 to reinforce an elastic force of the first elastic member 31. As will be described later, the elastic portion 30 is elastically deformed in response to a change in the posture of the probe 20 inside the housing 10, and biases the probe 20 in the direction to return to the posture of the probe 20 before the change.

In order to make the operation of the probe apparatus 1 easier to understand, the X direction, the Y direction, and the Z direction are defined as illustrated in FIG. 1. In FIG. 1, the X direction is a left-right direction in the page space, the Y direction is a depth direction in the page space, and the Z direction is an up-down direction in the page space. Further, in the Z direction, the direction in which the device 100 is positioned as viewed from the probe apparatus 1 is an upward direction, and the direction in which the probe apparatus 1 is positioned as viewed from the device 100 is a downward direction.

Although only one probe 20 of the probe apparatus 1 is illustrated in FIG. 1, the probe apparatus 1 may have a plurality of probes 20. For example, the probe apparatus 1 may have a configuration in which a plurality of probes 20 are arranged along the Y direction.

In FIG. 1, the probe apparatus 1 is arranged in the downward direction of the device 100 as viewed from the Z direction. The first contact portion 21 of the probe 20 is exposed on the first surface 11 of the housing 10, and the second contact portion 22 of the probe 20 is exposed on the second surface 12 of the housing 10. The probe 20 is arranged in the housing 10 such that the first contact portion 21 and the electrode terminal 101 of the device 100 come into contact with each other when the spacing between the probe apparatus 1 and the device 100 becomes narrow along the Z direction. Further, the probe apparatus 1 is arranged in the housing 10 such that the contact region 220 of the second contact portion 22 comes into contact with the electrode pad 201 of the substrate 200. As will be described later, at the time of inspection of the device 100, a position of the contact region 220 in the second contact portion 22 in contact with the electrode pad 201 changes due to the change in the position of the first contact portion 21 in the Z direction.

When viewed from the Y direction, the probe 20 has a curved shape in which a recess facing upward is formed. One end of the probe 20 positioned away from the outer portion of the probe 20 (hereinafter, it is referred to as a “curved portion”) facing the recess is the first contact portion 21. The other end of the probe 20 close to the recess is the second contact portion 22. A part of the arc-shaped region at the outer edge of the curved portion is the contact region 220. When the XY plane defined by the X direction and the Y direction is the projection plane, the projection line in the direction connecting the first contact portion 21 and the second contact portion 22 (hereinafter, it is referred to as “extending direction” of the probe 20) extends in the X direction. In other words, the probe 20 extends in the X direction when viewed from the Z direction.

The elastic portion 30 has a cylindrical shape in which an axial direction extends in the Y direction. That is, the axial direction of the elastic portion 30 is perpendicular to the direction in which the first contact portion 21 of the probe 20 is displaced and perpendicular to the direction in which the probe 20 extends. The elastic portion 30 abuts on the inner side of the recess of the probe 20. In other words, the elastic portion 30 is sandwiched between the surface of the recess of the probe 20 and the inner wall of the housing 10.

The first elastic member 31 may be made of an insulating material such as elastomer. For example, the first elastic member 31 may be made of a resin material such as silicone rubber or urethane rubber. For example, as illustrated in FIG. 2, the second elastic member 32 may be a cylindrical coil spring extending in the axial direction of the first elastic member 31. The central axis of the coil spring illustrated in FIG. 2 extends in the Y direction as in the axial direction of the cylindrical first elastic member 31. The second elastic member 32 is wholly embedded in the first elastic member 31. The second elastic member 32 may be made of a conductive coil spring such as metal or an insulating coil spring such as resin. The first elastic member 31 and the second elastic member 32 are integrated in such a way that an elastic force of the first elastic member 31 is reinforced by an elastic force of the second elastic member 32. Specifically, the first elastic member 31 and the second elastic member 32 are integrated in such a way that the elastic forces of the first elastic member 31 and the second elastic member 32 act in the same direction when the elastic portion 30 is compressed in the direction perpendicular to the Y-axis direction.

Although FIG. 2 exemplifies a case where the second elastic member 32 is a coil spring having a circular cross-sectional shape, the second elastic member 32 may of course have another shape. For example, by winding a ribbon material that is a flat plate having a cross-sectional shape with few irregularities, the coiled second elastic member 32 may be formed

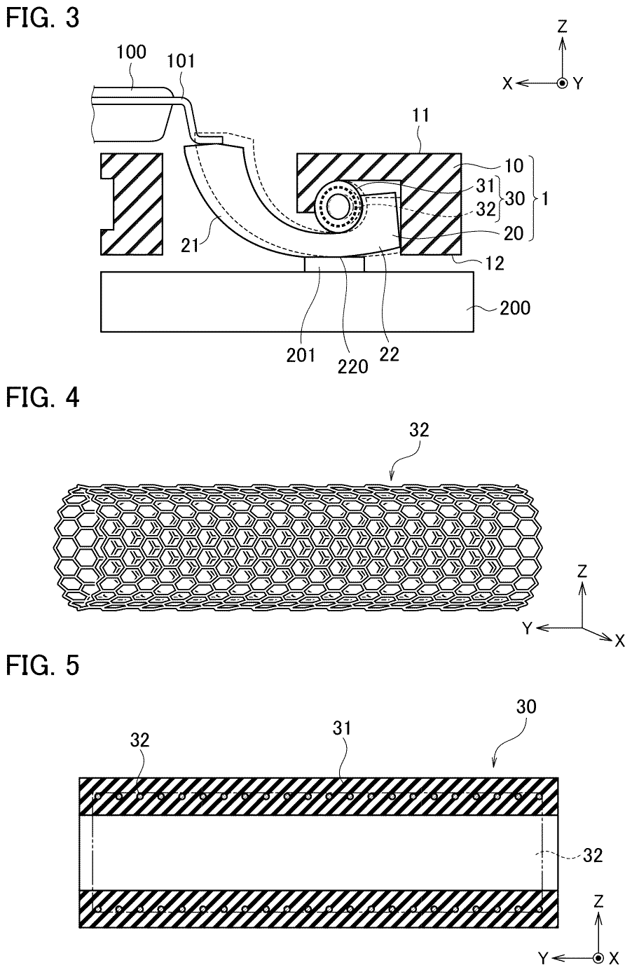

At the time of inspection of the device 100, as illustrated in FIG. 3, the electrode terminal 101 of the device 100 and the electrode pad 201 of the substrate 200 are electrically connected with each other by the conductive probe 20. That is, at the time of inspection of the device 100, the device 100 is moved relative to the probe apparatus 1 in the Z direction, thereby pressing the first contact portion 21 of the probe 20 against the electrode terminal 101 of the device 100. At this time, a posture of the probe 20 changes inside the housing 10 in a state in which the second contact portion 22 is in contact with the surface of the electrode pad 201 due to the pressing force applied to the first contact portion 21 between the first contact portion 21 and the electrode terminal 101.

Specifically, in response to the displacement of the first contact portion 21 in the Z direction caused by the pressing force applied to the first contact portion 21, a posture of the probe 20 changes inside the housing 10 while maintaining the state in which the second contact portion 22 is in contact with the electrode pad 201. As a posture of the probe 20 changes, the position of the contact region 220 in the second contact portion 22 in contact with the electrode pad 201 changes. In FIG. 3, the posture of the probe 20 and the shape of the elastic portion 30 in the state in which the first contact portion 21 and the electrode terminal 101 are in contact with each other (hereinafter, it is also referred to as “contact state”) are illustrated by solid lines. In FIG. 3, the posture of the probe 20 and the shape of the elastic portion 30 in the state in which the first contact portion 21 and the electrode terminal 101 are not in contact with each other (hereinafter, it is also referred to as “non-contact state”) are illustrated by dashed lines. In the contact state at the time of inspection of the device 100, a posture of the probe 20 changes such that the position of the contact region 220 is closer to the first contact portion 21 than in the non-contact state.

In the contact state, the elastic portion 30 is sandwiched between the probe 20 and the housing 10 and compressed, in response to the change in the posture of the probe 20 inside the housing 10. That is, in the contact state, the elastic portion 30 is elastically deformed. The elastically deformed elastic portion 30 biases the probe 20 in the direction in which the posture of the probe 20 returns to the posture in the non-contact state. In other words, the elastic portion 30 biases the probe 20 in such a way as to press the first contact portion 21 against the electrode terminal 101. Thus, a contact load applied to the probe 20 is caused by an elastic force of the elastic portion 30.

The elastic portion 30 of the probe apparatus 1 has a configuration in which the second elastic member 32 having elasticity is integrated with the first elastic member 31 such as an elastomer in such a way that the elastic forces act in the same direction. For this reason, the probe apparatus 1 makes it possible to suppress a decrease in the elastic force of the first elastic member 31, thereby improving the durability of the elastic portion 30.

During the inspection of the device 100, the state in which the first contact portion 21 abuts on the electrode terminal 101 and the second contact portion 22 abuts on the electrode pad 201 is maintained by an elastic force of the elastic portion 30. Thus, at the time of inspection of the device 100, the electrical connection between the electrode terminal 101 of the device 100 and the electrode pad 201 of the substrate 200 is ensured via the probe 20.

In the probe apparatus 1, as the contact region 220, a part of the arc-shaped region at the outer edge of the curved portion of the probe 20 comes into contact with the electrode pad 201 in a line extending in the Y direction. As illustrated in FIG. 3, the position of the contact region 220 in the contact state is closer to the first contact portion 21 than the position of the contact region 220 in the non-contact state. The position of the contact region 220 changes between the contact state and the non-contact state, since the position of the contact region 220 changes along the outer edge of the curved portion according to the change in the posture of the probe 20. The contact region 220 is included in the arc-shaped region of the curved portion, and thus the position of the contact region 220 in contact with the electrode pad 201 changes smoothly according to the change in the posture of the probe 20. For this reason, even if a posture of the probe 20 changes, damage to the second contact portion 22 and the electrode pad 201 can be suppressed.

As described above, at the time of inspection of the device 100, the elastic portion 30 sandwiched between the probe 20 and the housing 10 is elastically deformed by the change in the posture of the probe 20. The elastic portion 30 then biases the probe 20 such that the first contact portion 21 comes into contact with the electrode terminal 101 of the device 100 with a predetermined pressing force. That is, the elastic portion 30 biases the probe 20 in a direction that cancels the displacement of the first contact portion 21 caused by the pressing force applied to the first contact portion 21 when the first contact portion 21 is pressed against the electrode terminal 101. During the inspection of the device 100, that is, while the first contact portion 21 is in contact with the electrode terminal 101, the elastic portion 30 is in a compressively deformed state.

After the inspection of the device 100 is completed, the position of the device 100 relative to the probe apparatus 1 in the Z direction is changed so as to increase the spacing between the device 100 and the probe apparatus 1. By separating the electrode terminal 101 of the device 100 from the first contact portion 21 of the probe 20, the pressing force applied to the first contact portion 21 is eliminated. As a result, the shape of the elastic portion 30 returns to the non-contact state, and the posture of the probe 20 returns to the non-contact state due to the elastic force of the elastic portion 30.

The probe 20 is supported in the housing 10 such that the posture of the probe 20 can be changed in response to the displacement of the position of the first contact portion 21 in the Z direction. A posture of the probe 20 changes inside the housing 10 such that the position of the contact region 220 in the second contact portion 22 in contact with the electrode pad 201 changes in response to the displacement of the first contact portion 21 in the Z direction. For example, although not illustrated, a part of the probe 20 may be protruded and the protruded part of the probe 20 may be fitted into a support hole provided in the housing 10. Alternatively, a part of the probe 20 may be placed in a support portion of the housing 10 provided in the downward direction of the probe 20.

As described above, the probe apparatus 1 includes the probe 20 which simultaneously comes into contact with the electrode terminal 101 and the electrode pad 201, and the elastic portion 30 which biases the probe 20 by an elastic force when the probe 20 is in contact with the electrode terminal 101. The contact load applied to the probe 20 when the probe 20 and the electrode terminal 101 come into contact with each other is controlled by the elastic force of the elastic portion 30. The contact load increases by increasing the elastic force of the elastic portion 30, and the contact load decreases by decreasing the elastic force of the elastic portion 30.

Further, in the probe apparatus 1, the amount (hereinafter, it is also referred to as “stroke”) by which the first contact portion 21 is displaced by coming into contact with the electrode terminal 101 is controlled by the elastic force of the elastic portion 30. That is, the stroke decreases by increasing the elastic force of the elastic portion 30, and the stroke increases by decreasing the elastic force of the elastic portion 30.

By forming the first elastic member 31 into a cylindrical shape having a hollow portion therein, the magnitude of the contact load and stroke can be easily controlled. That is, by increasing the cylindrical first elastic member 31 in thickness from the outer peripheral portion to the hollow portion therein, the contact load can be increased and the stroke can be decreased. In contrast, by decreasing the cylindrical elastic portion 30 in thickness, the contact load can be decreased and the stroke can be increased.

For example, an elastic force of the elastic portion 30 is set in such a way that the displacement amount of the first contact portion 21 caused by coming into contact with the electrode terminal 101 is set to a predetermined value by adjusting a thickness of the first elastic member 31 from the outer peripheral portion of the first elastic member 31 to the hollow portion therein. For example, the predetermined value of the displacement amount of the first contact portion 21 is set in such a way that the length of the contact mark generated on the electrode terminal 101 when the probe 20 comes into contact with the electrode terminal 101 is set to a predetermined constraint value or less.

As described above, the probe apparatus 1 according to the first embodiment has a configuration in which the elastic portion 30 integrates the first elastic member 31 and the second elastic member 32. The elastic force of the first elastic member 31 such as an elastomer is reinforced by the second elastic member 32. Accordingly, the elastic stability and durability of the elastic portion 30 can be improved as compared with the case where the elastic portion 30 is made of a single material. As a result, the probe apparatus 1 enables the contact between the probe 20 and the electrode terminal 101 and the electrode pad 201 to be stabilized.

### Modified Example

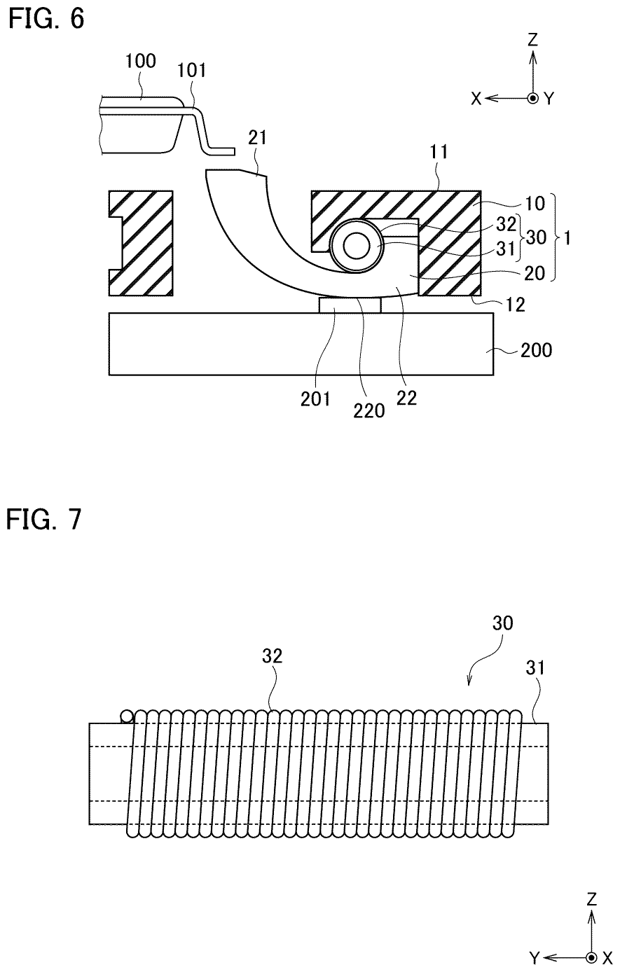

In the probe apparatus 1 according to the first embodiment, as illustrated in FIG. 4, the second elastic member 32 of the elastic portion 30 may be a mesh-like cylindrical body. The second elastic member 32 is embedded in the first elastic member 31 as illustrated in FIG. 5, and the axial direction of the second elastic member 32 is the axial direction of the first elastic member 31.

Even when the second elastic member 32 is a mesh-like cylindrical body, by integrating the first elastic member 31 and the second elastic member 32 in such a way that the elastic forces act in the same direction, it is possible to suppress a decrease in the elastic force of the first elastic member 31, thereby improving the durability of the elastic portion 30. Although FIG. 4 exemplifies a case where the second elastic member 32 has a honeycomb mesh structure, the second elastic member 32 may be any mesh-like cylindrical body as long as the elastic force acts in the same direction as the first elastic member 31 when the elastic portion 30 is deformed in compression.

### Second Embodiment

In the probe apparatus 1 according to a second embodiment, as illustrated in FIG. 6, at least a part of the second elastic member 32 is exposed on the surface of the first elastic member 31. FIG. 7 exemplifies a case where the second elastic member 32, which is a coil spring, is wholly arranged on the surface of the first elastic member 31. Alternatively, the first elastic member 31 and the second elastic member 32 may be integrated in such a way that the second elastic member 32 is embedded in the surface of the first elastic member 31 and the surface of the second elastic member 32 is exposed on the surface of the first elastic member 31. The probe apparatus 1 according to the second embodiment differs from that of the first embodiment in that at least a part of the second elastic member 32 is exposed on the surface of the first elastic member 31. The probe apparatus 1 according to the second embodiment is the same as that of the first embodiment in other configurations.

According to the probe apparatus 1 illustrated in FIG. 6, when a posture of the probe 20 changes at the time of inspection of the device 100, the elastic portion 30 sandwiched between the probe 20 and the housing 10 is elastically deformed, and the first contact portion 21 comes into contact with the electrode terminal 101 with a predetermined pressing force. During the inspection of the device 100, the elastic portion 30 is in a compressively deformed state. The elastic portion 30 biases the probe 20 in a direction that cancels the displacement of the first contact portion 21 caused by the pressing force applied to the first contact portion 21 when the first contact portion 21 is pressed against the electrode terminal 101.

Even when the second elastic member 32 is exposed on the surface of the first elastic member 31, the elastic force of the first elastic member 31 is reinforced by the second elastic member 32. Accordingly, the probe apparatus 1 according to the second embodiment makes it possible to suppress a decrease in the elastic force of the first elastic member 31, thereby improving the durability of the elastic portion 30 by integrating the first elastic member 31 and the second elastic member 32.

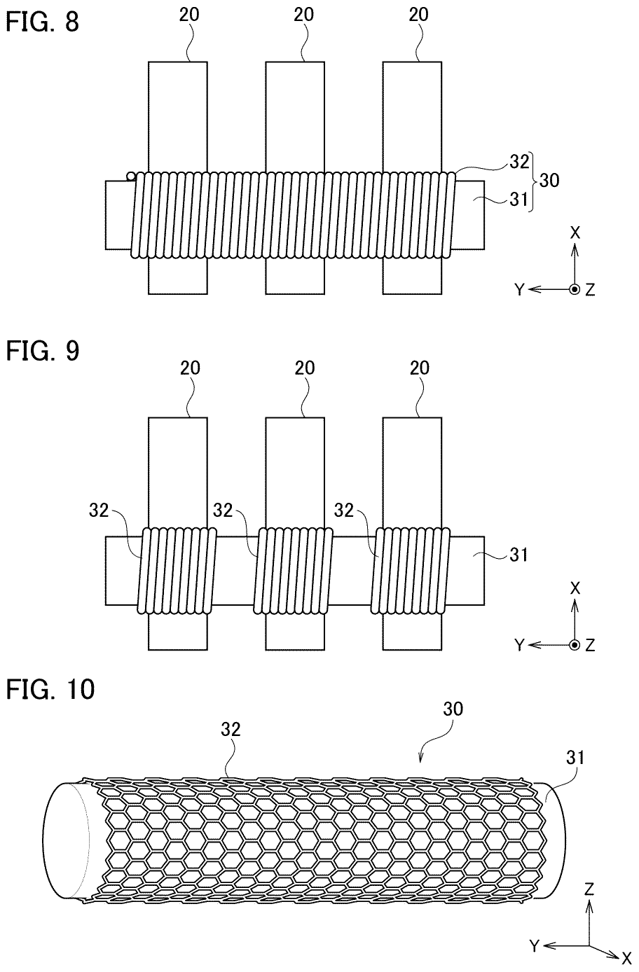

As illustrated in FIG. 8, when the same elastic portion 30 abuts on a plurality of probes 20, the second elastic member 32 may be made of an insulating material in such a way as to prevent a short circuit between the probes 20 via the second elastic member 32 exposed on the surface of the first elastic member 31. Alternatively, as illustrated in FIG. 9, the second elastic member 32 may be divided at a position between the probes 20. Even if the second elastic member 32 is made of a conductive material, by dividing the second elastic member 32 into a plurality of regions along the axial direction of the first elastic member 31, it is possible to prevent a short circuit between the probes 20 which may cause via the second elastic member 32.

As described above, in the probe apparatus 1 according to the second embodiment, the elastic force of the first elastic member 31 is reinforced by the second elastic member 32 integrated with the first elastic member 31. Accordingly, the probe apparatus 1 makes it possible to improve the elastic stability and durability of the elastic portion 30. In other respects, the probe apparatus 1 according to the second embodiment is substantially the same as that of the first embodiment, and thus a redundant description thereof will be omitted.

### Modified Example

In the probe apparatus 1 according to the second embodiment, as illustrated in FIG. 10, the second elastic member 32 arranged so as to be exposed on the surface of the first elastic member 31 may be a mesh-like cylindrical body. For example, the second elastic member 32 may have a honeycomb mesh structure as illustrated in FIG. 10, or may be a cylindrical body with other shaped meshes. The second elastic member 32 may be wholly arranged on the surface of the first elastic member 31, or the surface of the second elastic member 32 embedded in the surface of the first elastic member 31 may be exposed on the surface of the first elastic member 31. Even if the second elastic member 32 is a mesh-like cylindrical body, by integrating the first elastic member 31 and the second elastic member 32, it is possible to suppress a decrease in the elastic force of the first elastic member 31, thereby improving the durability of the elastic portion 30.

Also in the probe apparatus 1 according to the second embodiment, when the same elastic portion 30 abuts on a plurality of probes 20 as in FIG. 8, the second elastic member 32 may be made of an insulating material in such a way as to as to prevent a short circuit between the probes 20 via the second elastic member 32. Alternatively, the second elastic member 32 made of a conductive material may be divided at a position between the probes 20, thereby preventing a short circuit between the probes 20.

### Third Embodiment

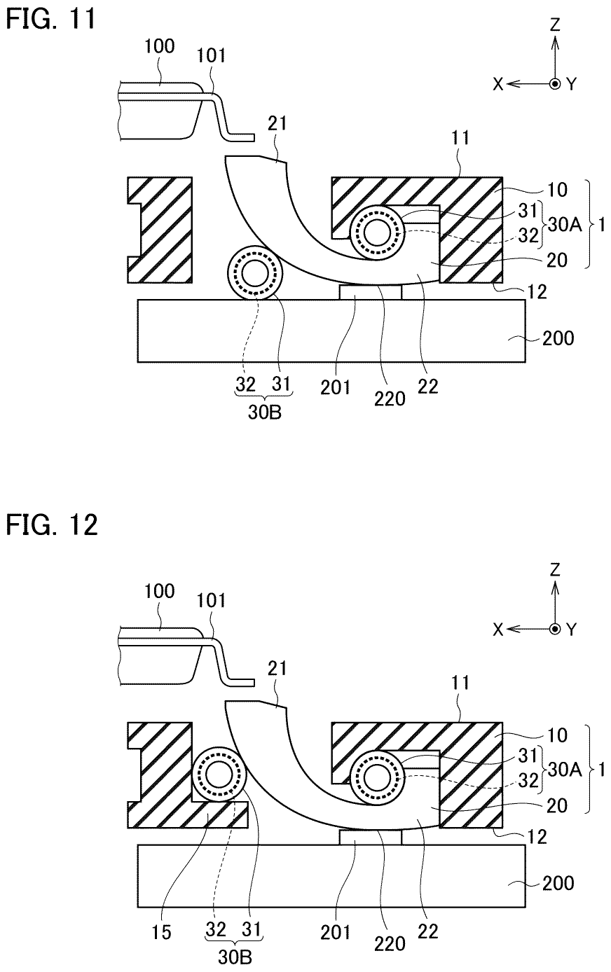

The probe apparatus 1 according to a third embodiment has a plurality of elastic portions 30 inside the housing 10 in which the first elastic member 31 and the second elastic member 32 are integrated. For example, as in the probe apparatus 1 illustrated in FIG. 11, a first elastic portion 30A and a second elastic portion 30B each abutting on the probe 20 are arranged inside the housing 10. As in the elastic portion 30 of the probe apparatus 1 illustrated in FIG. 1, the first elastic portion 30A is arranged inside the recess of the probe 20, and is sandwiched between the surface of the recess of the probe 20 and the inner wall of the housing 10. The second elastic portion 30B abuts on the probe 20 at a position separated from a position where the probe 20 abuts on the first elastic portion 30A. More specifically, the second elastic portion 30B abuts on the probe 20 at a position closer to the first contact portion 21 than the contact region 220. The second elastic portion 30B is arranged between the probe 20 and the substrate 200 in the downward direction of the first contact portion 21. For this reason, the second elastic portion 30B is elastically deformed between the probe 20 and the substrate 200 in response to a change in the posture of the probe 20 at the time of inspection of the device 100. In addition, as in the first elastic portion 30A, the second elastic portion 30B biases the probe 20 in the direction to return to the posture of the probe 20 before the change. In the following description, when each of the first elastic portion 30A and the second elastic portion 30B is not limited, they will be referred to as the elastic portion 30.

The probe apparatus 1 according to the third embodiment differs from that of the first embodiment in that the plurality of elastic portions 30 are provided inside the housing 10 as described above. The probe apparatus 1 according to the third embodiment is the same as that of the first embodiment in other configurations. For example, according to the probe apparatus 1 illustrated in FIG. 11, when a posture of the probe 20 changes at the time of inspection of the device 100, the plurality of elastic portions 30 are elastically deformed, and the first contact portion 21 comes into contact with the electrode terminal 101 with a predetermined pressing force. During the inspection of the device 100, each of the plurality of elastic portions 30 is in a compressively deformed state. The plurality of elastic portions 30 bias the probe 20 in a direction that cancels the displacement of the first contact portion 21 caused by the pressing force applied to the first contact portion 21 when the first contact portion 21 is pressed against the electrode terminal 101.

FIG. 11 exemplifies a case where the elastic portion 30 has a structure in which the second elastic member 32 is embedded in the first elastic member 31. However, as in the probe apparatus 1 according to the second embodiment, the first elastic member 31 and the second elastic member 32 may be integrated in such a way that at least a part of the second elastic member 32 is exposed on the surface of the first elastic member 31. For example, the second elastic member 32 may be wholly arranged on the surface of the first elastic member 31, or a part of the second elastic member 32 may be embedded in the surface of the first elastic member 31.

The probe apparatus 1 according to the third embodiment makes it possible to increase the elastic force for biasing the probe 20 by having the plurality of elastic portions 30. The elastic portion 30 in which the first elastic member 31 and the second elastic member 32 are integrated makes it possible to suppress a decrease in the elastic force of the first elastic member 31, thereby improving the durability of the elastic portion 30. In other respects, the probe apparatus 1 according to the third embodiment is substantially the same as that of the first embodiment and the second embodiment, and thus a redundant description thereof will be omitted.

### Modified Example

In the probe apparatus 1 according to the third embodiment, the second elastic portion 30B may be arranged between the probe 20 and the housing 10. For example, as illustrated in FIG. 12, the second elastic portion 30B may be arranged on a pedestal portion 15 of the housing 10 provided in the downward direction of the first contact portion 21 of the probe 20, and the second elastic portion 30B may be elastically deformed between the probe 20 and the pedestal portion 15.

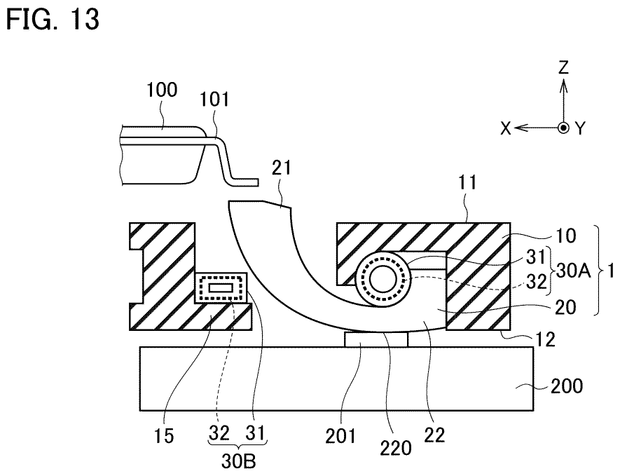

Further, as illustrated in FIG. 13, the outer edge of the first elastic member 31 of the second elastic portion 30B as viewed from the Y direction may be formed into a rectangular shape. For example, the first elastic member 31 of the second elastic portion 30B may have a tubular shape having a hollow portion. When the outer edge of the first elastic member 31 is formed into a rectangular shape, by winding a ribbon material that is a flat plate having a cross-sectional shape with few irregularities, the coiled second elastic member 32 may be formed, for example.

### Other Embodiments

The embodiments of the present invention have been described above, but the statements and drawings forming part of this disclosure should not be understood as limiting the invention. Various alternative embodiments, examples, and operating techniques will be apparent to those skilled in the art from this disclosure.

For example, although the case where the elastic portion 30 has a cylindrical shape has been described above as an example, the elastic portion 30 is not limited to having a cylindrical shape. For example, the elastic portion 30 may have a cylindrical shape without a hollow portion, or the outer edge of the elastic portion 30 as viewed from the Y direction may have a polygonal shape instead of a circular shape. In addition, the second elastic member 32 may be a plate-like elastic member. Although the case where the electrode terminal 101 of the device 100 is a lead electrode has been described above as an example, the electrode terminal 101 may be a pad electrode, a bump electrode, or an electrode having a shape other than a pad electrode and a bump electrode.

When the second elastic member 32 is made of a conductive material such as a metal spring, a measured value of the high-frequency characteristics of the device 100 and the like may be electrically influenced by the second elastic member 32 because the distance between the second elastic member 32 and the probe 20 is close. Accordingly, measures may be taken such as connecting the end of the second elastic member 32 made of a conductive material to the ground potential (GND).

Thus, the present invention will of course include various embodiments and the like which are not described herein.

### REFERENCE SIGNS LIST

1: Probe apparatus
10: Housing
11: First surface
12: Second surface
20: Probe
21: First contact portion
22: Second contact portion
30: Elastic portion
31: First elastic member
32: Second elastic member
100: Device
101: Electrode terminal
200: Substrate
201: Electrode pad

1. A probe apparatus that electrically connects an electrode terminal of a device to be inspected and an electrode pad connected to an inspection device, the probe apparatus comprising:
a housing that has a first surface and a second surface facing the first surface;
a conductive probe that has a first contact portion exposed on the first surface and a second contact portion exposed on the second surface and is supported by the housing, a posture of the probe changing inside the housing such that a position of a contact region in the second contact portion in contact with the electrode pad changes in response to a displacement of the first contact portion; and
an elastic portion that is arranged inside the housing, and has a first elastic member and a second elastic member integrated with the first elastic member to reinforce an elastic force of the first elastic member, the elastic portion being elastically deformed in response to a change in the posture of the probe inside the housing, and biasing the probe in a direction that cancels the displacement of the first contact portion.

2. The probe apparatus according to claim 1, wherein the first elastic member is an elastomer.

3. The probe apparatus according to claim 1, wherein the second elastic member is embedded in the first elastic member.

4. The probe apparatus according to claim 1, wherein at least a part of the second elastic member is exposed on a surface of the first elastic member.

5. The probe apparatus according to claim 3, wherein the second elastic member is a cylindrical coil spring.

6. The probe apparatus according to claim 3, wherein the second elastic member is a mesh-like cylindrical body.

7. The probe apparatus according to claim 3, wherein the first elastic member has a hollow portion therein.

8. The probe apparatus according to claim 7, wherein
an elastic force of the elastic portion is set in such a way that a displacement amount of the first contact portion caused by coming into contact with the electrode terminal is set to a predetermined value by adjusting a thickness of the first elastic member from an outer peripheral portion to the hollow portion of the first elastic member, and
the predetermined value of the displacement amount is set in such a way that a length of a contact mark generated on the electrode terminal when the probe comes into contact with the electrode terminal is set to a predetermined constraint value or less.
